(19) United States
(12) Patent Application Publication
(10) Pub. No.: US 2022/0282035 A1
(43) Pub. Date: Sep. 8, 2022

(54) PHOTO-SENSITIVE COMPOSITION FOR INSULATING FILM FOR TOUCH PANEL OF ORGANIC LIGHT EMITTING DISPLAY DEVICE

(71) Applicant: DUK SAN NEOLUX CO., LTD., Cheonan-si (KR)

(72) Inventors: Changmin LEE, Cheonan-si (KR); Yun Jong KO, Cheonan-si (KR); Hyunsang CHO, Cheonan-si (KR); Jaehyun LIM, Cheonan-si (KR); Seo Jeong JEON, Cheonan-si (KR); Kyoung Chul KIM, Cheonan-si (KR); Soung Yun MUN, Cheonan-si (KR)

(73) Assignee: DUK SAN NEOLUX CO., LTD., Cheonan-si (KR)

(21) Appl. No.: 17/652,515

(22) Filed: Feb. 25, 2022

(30) Foreign Application Priority Data
Mar. 2, 2021 (KR) 10-2021-0027353

(51) Int. Cl. C08G 63/668; H01L 27/32; G06F 3/044

(52) U.S. Cl. CPC C08G 63/668; H01L 27/323; G06F 3/044

(57) ABSTRACT

Provided herein are a touch panel with excellent sensitivity by implementing an insulating film for a touch panel with a low dielectric constant from a photo-sensitive composition using hollow silica particles, and an organic light emitting display device to which the touch panel is applied.

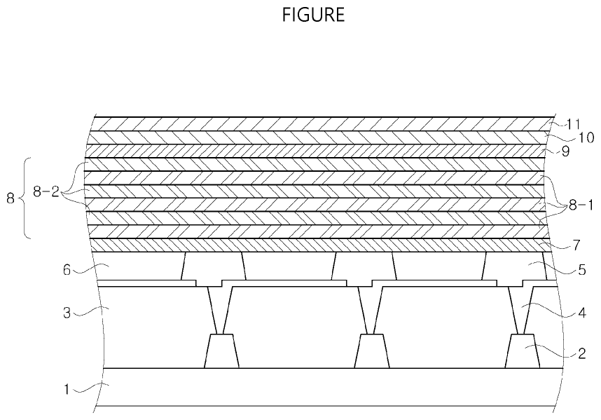

### BACKGROUND OF THE DISCLOSURE

### Field of the Disclosure

The present disclosure relates to an organic light emitting display device and a photo-sensitive composition for forming an insulating film used in a touch panel of an organic light emitting display device.

### Related Art

An organic light emitting display device is provided with an organic light emitting device which includes a hole injection electrode, an electron injection electrode, and an organic light emitting layer interposed therebetween, and it is a self-luminous display device where excitons, which are generated by a linkage between the holes injected from the hole injection electrode and the electrons injected from the electron injection electrode in the organic light emitting layer, generate light as they fall from an excited state to a ground state.

Since the organic light emitting display device, which is a self-luminous display device, does not require a separate light source, it can be operated at low voltage, can be configured in a light and thin shape, and has been highlighted as a next-generation display device due to its high quality characteristics, such as a wide viewing angle, high contrast, and fast response speed.

However, since the organic light emitting display device has a property of being deteriorated by external moisture, oxygen, etc., the organic light emitting device is sealed so as to protect the organic light emitting device from external moisture, oxygen, etc.

Recently, for the purpose of thinning and/or flexibility of the organic light emitting display device, thin film encapsulation (TFE) that consists of a plurality of inorganic films or a plurality of layers including an organic film and an inorganic film is used as a means for sealing the organic light emitting device.

Meanwhile, since the touch panel is an input device that can easily be used by anyone, regardless of age or gender, by interactively and intuitively manipulating the buttons displayed on the display with a finger, it is currently being applied in many fields (e.g., issuance devices for banks and government offices, various medical equipment, information for tourism and major institutions, transportation information, etc.).

Known methods of implementing a touch panel include a resistive film method, a photo-sensitive method, a capacitive method, etc. Such a touch panel is generally configured to be linked to the outer surface of a flat panel display device (e.g., an organic light emitting display device), and there are problems in that the overall thickness of the product is increased and manufacturing cost is increased when a separately manufactured touch panel and a flat panel display are linked to each other to be used.

In order to improve the above problems, recently, a built-in touch panel in which a capacitive touch panel using static electricity is placed inside a display is widely used. In the case of the built-in capacitive touch panel, two layers of electrodes are prepared inside the touch panel, and an insulating film is disposed between the two electrodes. In particular, a high-sensitivity touch panel can be manufactured only when the insulating film has excellent insulating properties. Therefore, an insulating film for a touch panel having excellent low dielectric constant characteristics is required.

### SUMMARY

In order to solve the problems in the related art, in an embodiment, the present disclosure provides a touch panel with excellent sensitivity by implementing an insulating film for a touch panel with a low dielectric constant from a photo-sensitive composition using hollow silica particles, and also provides an organic light emitting display device to which the touch panel is applied.

The present disclosure provides a photo-sensitive composition for an insulating film for a touch panel of an organic light emitting display device, in which the photo-sensitive composition includes an alkali soluble resin; a reactive unsaturated compound; a photo-initiator; hollow silica; and a solvent.

The alkali soluble resin preferably includes a copolymer resin that includes a repeating unit represented by the following Formula (1), a repeating unit represented by the following Formula (2), and a repeating unit represented by the following Formula (3):

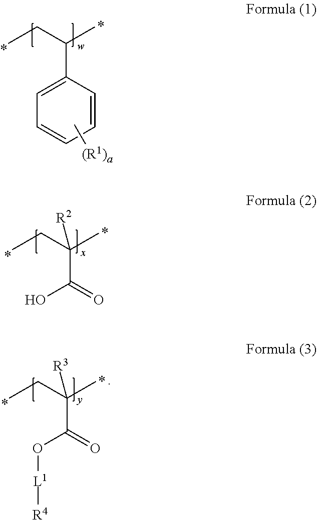

In another specific embodiment, the present disclosure provides an insulation film for a touch panel of an organic light emitting display device which is formed from the photo-sensitive composition, in which the dielectric constant is in the range of 2.50 to 3.50 when the frequency of the AC voltage is in the range of 50 KHz to 300 KHz.

In still another specific embodiment, the present disclosure provides a touch panel which includes a first touch electrode; a second touch electrode disposed on the first touch electrode; and the insulating layer disposed between the first touch electrode and the second touch electrode.

In still another specific embodiment, the present disclosure provides an organic light emitting display device, which includes a substrate; an organic light emitting device layer on the substrate; a sealing layer disposed on the organic light emitting device layer; and the touch panel disposed on the sealing layer.

### Advantageous of the Invention

The photo-sensitive composition according to an embodiment of the present disclosure can provide a touch panel with excellent sensitivity by implementing an insulating film for a touch panel with a low dielectric constant.

### BRIEF DESCRIPTION OF THE DRAWINGS

The FIGURE conceptually illustrates a touch panel for implementing the present disclosure.

### DESCRIPTION OF EXEMPLARY EMBODIMENTS

Hereinafter, some Examples of the present disclosure will be described in detail with reference to exemplary drawings. In adding reference numerals to components of each drawing, the same components may have the same reference numerals even though they are indicated on different drawings.

When it is determined that a detailed description of a related known constitution or function may obscure the gist of the present disclosure in describing the present disclosure, the detailed description thereof may be omitted. When the expressions “includes”, “has”, “consisting of”, etc. mentioned in this specification are used, other parts may be added unless “only” is used. When a component is expressed in the singular form, it may include a case in which the plural form is included unless otherwise explicitly stated.

In describing the components of the present disclosure, terms such as first, second, A, B, (a), (b), etc. may be used. These terms are only for distinguishing the components from other components, and the essence, order, sequence, the number, etc. of the components are not limited by the terms.

In the description of the positional relationship of the components, when two or more components are described as being “connected”, “linked”, or “fused”, etc., the two or more components may be directly “connected”, “linked”, or “fused”, but it should be understood that the two or more components may also be “connected”, “linked”, or “fused” by way of a further “interposition” of a different component. In particular, the different component may be included in any one or more of the two or more components that are to be “connected”, “linked”, or “fused” to each other.

In addition, when a component (e.g., a layer, a film, a region, a plate, etc.) is described to be “on top” or “on” of another component, it should be understood that this may also include a case where another component is “immediately on top of” as well as a case where another component is disposed therebetween. In contrast, it should be understood that when a component is described to be “immediately on top of” another component, it means that there is no other component disposed therebetween.

In the description of the temporal flow relationship related to the components, the operation method or the production method, for example, when the temporal precedence or flow precedence is described by way of “after”, “subsequently”, “thereafter”, “before”, etc., it may also include cases where the flow is not continuous unless terms such as “immediately” or “directly” is used.

Meanwhile, when the reference is made to numerical values or corresponding information for components, numerical values or corresponding information may be interpreted as including an error range that may occur due to various factors (e.g., procedural factors, internal or external shocks, noise, etc.) even if there is no explicit description thereon.

The terms used in this specification and the appended claims are as follows, unless otherwise stated, without departing from the spirit of the present disclosure.

As used herein, the term “halo” or “halogen” includes fluorine (F), chlorine (Cl), bromine (Br), and iodine (I), unless otherwise specified.

As used herein, the term “alkyl” or “alkyl group” has 1 to 60 carbons linked by a single bond unless otherwise specified, and refers to a radical of a saturated aliphatic functional group, including a linear chain alkyl group, a branched chain alkyl group, a cycloalkyl (alicyclic) group, an alkyl-substituted cycloalkyl group, and a cycloalkyl-substituted alkyl group.

As used herein, the term “haloalkyl group” or “halogenalkyl group” refers to an alkyl group in which a halogen is substituted, unless otherwise specified.

As used herein, the term “alkenyl” or “alkynyl” has a double bond or a triple bond, respectively, includes a linear or branched chain group, and has 2 to 60 carbon atoms, unless otherwise specified, but is not limited thereto.

As used herein, the term “cycloalkyl” refers to an alkyl which forms a ring having 3 to 60 carbon atoms unless otherwise specified, but is not limited thereto.

As used herein, the term “an alkoxy group” or “alkyloxy group” refers to an alkyl group to which an oxygen radical is linked, and has 1 to 60 carbon atoms unless otherwise specified, but is not limited thereto.

As used herein, the term “alkenoxyl group”, “alkenoxy group”, “alkenyloxyl group”, or “alkenyloxy group” refers to an alkenyl group to which an oxygen radical is linked, and has 2 to 60 carbon atoms unless otherwise specified, but is not limited thereto.

As used herein, the terms “aryl group” and “arylene group” each have 6 to 60 carbon atoms unless otherwise specified, but are not limited thereto. As used herein, the aryl group or arylene group includes a single ring type, a ring assembly, a fused multiple ring compound, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

As used herein, the term “ring assembly” means that two or more ring systems (monocyclic or fused ring systems) are directly connected to each other through a single bond or double bond, in which the number of direct links between such rings is one less than the total number of ring systems in the compound. In the ring assembly, the same or different ring systems may be directly connected to each other through a single bond or double bond.

As used herein, since the aryl group includes a ring aggregate, the aryl group includes biphenyl and terphenyl in which a benzene ring, which is a single aromatic ring, is connected by a single bond. In addition, since the aryl group also includes a compound in which an aromatic ring system fused to an aromatic single ring is connected by a single bond, it also includes, for example, a compound in which a benzene ring (which is an aromatic single ring) and fluorine (which is a fused aromatic ring system) are linked by a single bond.

As used herein, the term “fused multiple ring system” refers to a fused ring form in which at least two atoms are shared, and it includes a form in which ring systems of two or more hydrocarbons are fused, a form in which at least one heterocyclic system including at least one heteroatom is fused, etc. Such a fused multiple ring system may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

As used herein, the term “a spiro compound” has a spiro union, and the spiro union refers to a linkage in which two rings share only one atom. In particular, the atom shared by the two rings is called a “spiro atom”, and they are each called “monospiro-”, “dispiro-”, and “trispiro-” compounds depending on the number of spiro atoms included in a compound.

As used herein, the terms “fluorenyl group”, “fluorenylene group”, and “fluorenetriyl group” refer to a monovalent, divalent, or trivalent functional group in which R, R′, R″, and R′″ are all hydrogen in the following structures, respectively, unless otherwise specified; “substituted fluorenyl group”, “substituted fluorenylene group”, or “substituted fluorenetriyl group” means that at least one of the substituents R, R′, R″, and R′″ is a substituent other than hydrogen, and include cases where R and R′ are bound to each other to form a spiro compound together with the carbon to which they are linked. As used herein, all of the fluorenyl group, the fluorenylene group, and the fluorenetriyl group may also be referred to as a fluorene group regardless of valences such as monovalent, divalent, trivalent, etc.

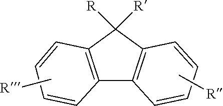

In addition, the R, R′, R″, and R′″ may each independently be an alkyl group having 1 to 20 carbon atoms, an alkenyl group having 1 to 20 carbon atoms, an aryl group having 6 to 30 carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene and 9,9′-spirobi[9H-fluorene].

As used herein, the term “heterocyclic group” includes not only aromatic rings (e.g., “heteroaryl group” and “heteroarylene group”), but also non-aromatic rings, and may refer to a ring having 2 to 60 carbon atoms each including one or more heteroatoms unless otherwise specified, but is not limited thereto. As used herein, the term “heteroatom” refers to N, O, S, P, or Si unless otherwise specified, and a heterocyclic group refers to a monocyclic group including a heteroatom, a ring assembly, a fused multiple ring system, a spiro compound, etc.

For example, the “heterocyclic group” may include a compound including a heteroatom group (e.g., SO₂, P═O, etc.), such as the compound shown below, instead of carbon that forms a ring.

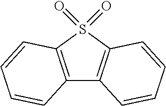 [SMILES: O=S1(=O)c2ccccc2-c2ccccc21]

As used herein, the term “ring” includes monocyclic and polycyclic rings, and includes heterocycles containing at least one heteroatom as well as hydrocarbon rings, and includes aromatic and non-aromatic rings.

As used herein, the term “polycyclic” includes ring assemblies (e.g., biphenyl, terphenyl, etc.), fused multiple ring systems, and spiro compounds, includes non-aromatic as well as aromatic compounds, and includes heterocycles containing at least one heteroatom as well as hydrocarbon rings.

As used herein, the term “alicyclic group” refers to cyclic hydrocarbons other than aromatic hydrocarbons, and it includes monocyclic, ring assemblies, fused multiple ring systems, spiro compounds, etc., and refers to a ring having 3 to 60 carbon atoms unless otherwise specified, but is not limited thereto. For example, when benzene (i.e., an aromatic ring) and cyclohexane (i.e., a non-aromatic ring) are fused, it also corresponds to an aliphatic ring.

Additionally, when prefixes are named consecutively, it means that the substituents are listed in the order they are described. For example, in the case of an arylalkoxy group, it means an alkoxy group substituted with an aryl group; in the case of an alkoxycarbonyl group, it means a carbonyl group substituted with an alkoxy group; additionally, in the case of an arylcarbonylalkenyl group, it means an alkenyl group substituted with an arylcarbonyl group, in which the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁₋₃₀ alkyl group, a C₁₋₃₀ alkoxy group, a C₁₋₃₀ alkylamine group, a C₁₋₃₀ alkylthiophene group, a C₆₋₃₀ arylthiophene group, a C₂₋₃₀ alkenyl group, a C₂₋₃₀ alkynyl group, a C₃₋₃₀ cycloalkyl group, a C₆₋₃₀ aryl group, a C₆₋₃₀ aryl group substituted with deuterium, a C₈₋₃₀ arylalkenyl group, a silane group, a boron group, a germanium group, and a C₂₋₃₀ heterocyclic group containing at least one heteroatom selected from the group consisting of O, N, S, Si, and P, but is not limited to these substituents.

As used herein, the “names of functional groups” corresponding to the aryl group, arylene group, heterocyclic group, etc. exemplified as examples of each symbol and a substituent thereof may be described as “a name of the functional group reflecting its valence”, and may also be described as the “name of its parent compound”. For example, in the case of “phenanthrene”, which is a type of an aryl group, the names of the groups may be described such that the monovalent group as “phenanthryl (group)”, and the divalent group as “phenanthrylene (group)”, etc., but may also be described as “phenanthrene”, which is the name of its parent compound, regardless of its valence.

Similarly, in the case of pyrimidine, it may be described regardless of its valence, or in the case of being monovalent, it may be described as pyrimidinyl (group); and in the case of being divalent, it may be described as the “name of the group” of the valence (e.g., pyrimidinylene (group)). Therefore, as used herein, when the type of a substituent is described as the name of its parent compound, it may refer to an n-valent “group” formed by detachment of a hydrogen atom linked to a carbon atom and/or hetero atom of its parent compound.

In addition, in describing the names of the compounds or the substituents in the present specification, the numbers or letters indicating positions may be omitted. For example, pyrido[4,3-d]pyrimidine may be described as pyridopyrimidine; benzofuro[2,3-d]pyrimidine as benzofuropyrimidine; 9,9-dimethyl-9H-fluorene as dimethylfluorene, etc. Therefore, both benzo[g]quinoxaline and benzo[f]quinoxaline may be described as benzoquinoxaline.

In addition, unless there is an explicit description, the formulas used in the present disclosure are applied in the same manner as in the definition of substituents by the exponent definition of the formula below.

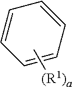

In particular, when a is an integer of 0, it means that the substituent R¹ is absent, that is, when a is 0, it means that all hydrogens are linked to carbons that form a benzene ring, and in this case, the formula or compound may be described while omitting the indication of the hydrogen linked to the carbon. In addition, when a is an integer of 1, one substituent R¹ may be linked to any one of the carbons forming a benzene ring; when a is an integer of 2 or 3, it may be linked, for example, as shown below; even when a is an integer of 4 to 6, it may be linked to the carbon of a benzene ring in a similar manner; and when a is an integer of 2 or greater, R¹ may be the same as or different from each other.

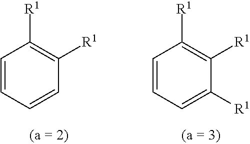

Unless otherwise specified in the present application, forming a ring means that neighboring groups bind to one another to form a single ring or fused multiple ring, and the single ring and the formed fused multiple ring include a heterocycle containing at least one heteroatom as well as a hydrocarbon ring, and may include aromatic and non-aromatic rings.

In addition, unless otherwise specified in the present specification, when indicating a condensed ring, the number in “number-condensed ring” indicates the number of rings to be condensed. For example, a form in which three rings are condensed with one another (e.g., anthracene, phenanthrene, benzoquinazoline, etc.) may be expressed as a 3-condensed ring.

Meanwhile, as used herein, the term “bridged bicyclic compound” refers to a compound in which two rings share 3 or more atoms to form a ring, unless otherwise specified. In particular, the shared atoms may include carbon or a hetero atom.

In the present disclosure, an organic electric device may refer to a component(s) between an anode and a cathode, or may refer to an organic light emitting diode which includes an anode, a cathode, and a component(s) disposed therebetween.

Additionally, in some cases, the display device in the present disclosure may refer to an organic electric device, an organic light emitting diode, and a panel including the same, or may refer to an electronic device including a panel and a circuit. In particular, for example, the electronic device may include a lighting device, a solar cell, a portable or mobile terminal (e.g., a smart phone, a tablet, a PDA, an electronic dictionary, a PMP, etc.), a navigation terminal, a game machine, various TV sets, various computer monitors, etc., but is not limited thereto, and may be any type of device as long as it includes the component(s).

Hereinafter, embodiments of the present disclosure will be described in detail. However, these embodiments are provided for illustrative purposes, and the present disclosure is not limited thereby, and the present disclosure is only defined by the scope of the claims to be described later.

The photo-sensitive composition for an insulating film for a touch panel of the organic light emitting display device according to a specific embodiment of the present disclosure includes an alkali soluble resin, a reactive unsaturated compound, a photo-initiator, hollow silica, and a solvent.

Hereinafter, each component will be described in detail.

(1) Alkali Soluble Resin

The photo-sensitive composition for an insulating film for a touch panel of the organic light emitting display device according to a specific embodiment of the present disclosure includes a copolymer resin that includes a repeating unit represented by the following Formula (1), a repeating unit represented by the following Formula (2), and a repeating unit represented by the following Formula (3).

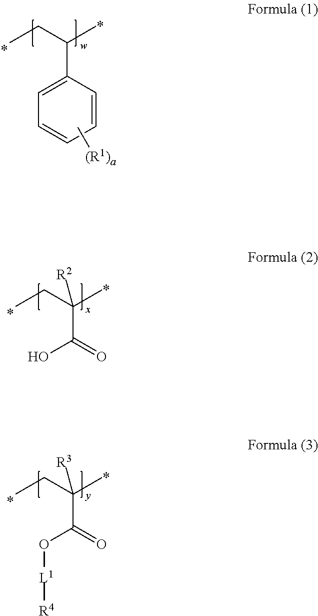

In Formula (1) to Formula (3) above,

1) * represents a binding site;

2) R¹ is hydrogen; deuterium; a halogen; a fluorenyl group; a carbonyl group; an ester group; an ether group; a sulfonic acid group; a C₆₋₃₀ aryl group; a C₂₋₃₀ heterocyclic group containing at least one heteroatom among O, N, S, Si, and P; a C₆₋₃₀ of used ring group of a aliphatic ring and a aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; or a C₁₋₂₀ alkoxycarbonyl group;

3) a is an integer from 1 to 5;

4) R² to R⁴ are each independently hydrogen; deuterium; a halogen; a fluorenyl group; a C₆₋₃₀ aryl group; a C₂₋₃₀ heterocyclic group containing at least one heteroatom among O, N, S, Si, and P; a C₆₋₃₀ fused ring group of a aliphatic ring and a aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; or a C₁₋₂₀ alkoxycarbonyl group;

5) L¹ is a single bond; a fluorenylene group; C₁₋₃₀ alkylene; C₁₋₃₀ alkoxylene; C₁₋₃₀ alkenylene; C₆₋₃₀ arylene; C₂₋₃₀ heterocyclic ring; or C₃₋₃₀ cycloalkylene;

6) w is 0.4 to 0.7 (a mole fraction of the repeating unit represented by Formula (1) among resin molecules); x is 0.1 to 0.3 (a mole fraction of the repeating unit represented by Formula (2) among resin molecules); and y is 0.1 to 0.3 (a mole fraction of the repeating unit represented by Formula (3) among resin molecules);

7) R¹ to R⁴ may bind between the neighboring groups to form a ring; and

8) the R¹ to R⁴, the L¹, and the ring formed by a mutual binding between the neighboring groups may be each further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group containing at least one heteroatom among O, N, S, Si, and P; a C₃₋₃₀ alicyclic group; a C₇₋₃₀ arylalkyl group; a C₈₋₃₀ arylalkenyl group; and a combination thereof, or may form a ring between the neighboring substituents.

When R¹ to R⁴ are an aryl group, R¹ to R⁴ may preferably be a C₆₋₃₀ aryl group, and more preferably a C₆₋₁₈ aryl group (e.g., phenyl, biphenyl, naphthyl, terphenyl, etc.).

When R¹ to R⁴ area heterocyclic group, R¹ to R⁴ may preferably be a C₂₋₃₀ heterocyclic group, and more preferably a C₂₋₁₈ heterocyclic group (e.g., dibenzofuran, dibenzothiophene, naphthobenzothiophene, naphthobenzofuran, etc.).

When R¹ to R⁴ are a heterocyclic group, R¹ to R⁴ may preferably be 9,9-dimethyl-9H-fluorene, 9,9-diphenyl-9H-a fluorenyl group, 9,9′-spirobifluorene, etc.

When L¹ is an arylene group, L¹ may preferably be a C₆₋₃₀ arylene group, and more preferably a C₆₋₁₈ arylene group (e.g., phenyl, biphenyl, naphthyl, terphenyl, etc.).

When R¹ to R⁴ are an aryl group, R¹ to R⁴ may preferably be a C₁₋₁₀ alkyl group (e.g., methyl, t-butyl, etc.).

When R¹ to R⁴ are an alkoxyl group, R¹ to R⁴ may preferably be a C₁₋₂₀ alkoxyl group, and more preferably a C₁₋₁₀ alkoxyl group (e.g., methoxy, t-butoxy, etc.).

The ring formed by a mutual binding between the neighboring groups of R¹ to R⁴ and L¹ may be a C₆₋₆₀ aromatic ring group; a fluorenyl group; a C₂₋₆₀ heterocyclic group containing at least one heteroatom among O, N, S, Si, and P; or a C₃₋₆₀ alicyclic group, and for example, when an aromatic ring is formed by a mutual binding between the neighboring groups, preferably a C₆₋₂₀ aromatic ring, and more preferably a C₆₋₁₄ aromatic ring (e.g., benzene, naphthalene, phenanthrene, etc.) may be formed.

In the repeating unit structure represented by Formula (3) above, R⁴ is preferably a heterocyclic group, more preferably, it is a heterocyclic group containing oxygen (O), even more preferably it is a saturated heterocyclic ring containing oxygen (O), and most preferably, the structure of Formula (3-1), Formula (3-2), or Formula (3-3) below, but is not limited thereto.

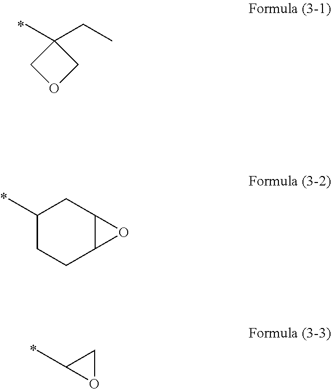

When the repeating unit represented by Formula (3) includes structures such as Formula (3-1), Formula (3-2), and Formula (3-3), a crosslinking can be formed between copolymer resins. Accordingly, when the insulating film of a touch panel of an organic light emitting display device is formed, the degree of curing of the insulating film pattern is improved, thereby improving the stability and durability of the insulating film.

The copolymer resin may have a weight average molecular weight of 1,000 g/molto 200,000 g/mol, preferably 5,000 g/molto 50,000 g/mol, and more preferably 5,000 g/molto 30,000 g/mol. When the weight average molecular weight of the copolymer resin is within the above range, there is an effect of reducing the loss of film thickness during the developing process, and there is an effect of reducing the generation of residues during the preparation of a pattern layer.

It is preferable that the mole fraction of the repeating unit represented by Formula (1) in the copolymer resin molecules is in the range of 0.4 to 0.7, and that the mole fraction of the repeating units represented by Formula (2) and Formula (3) is in the range of 0.1 to 0.3. When the repeating unit has the above mole fraction, the photo-sensitive composition of the present disclosure can exhibit a dielectric constant suitable for use as an insulating film for a touch panel of an organic light emitting display device, while maintaining adequate developability during patterning, thereby exhibiting an extremely excellent pattern resolution.

The copolymer resin may further include a repeating unit represented by Formula (4) below, in addition to the repeating units represented by Formula (1), Formula (2), and Formula (3).

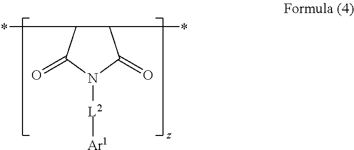

In Formula (4) above,

1) * represents a bonding part;

2) Ar¹ is hydrogen; deuterium; a halogen; a fluorenyl group; a C₃₋₃₀ cycloalkyl group; a C₆₋₃₀ aryl group; a C₂₋₃₀ heterocyclic group comprising at least one heteroatom among O, N, S, Si, and P; a C₆₋₃₀ fused ring group of a aliphatic ring and an aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; or a C₁₋₂₀ alkoxycarbonyl group;

3) L² is a single bond; a fluorenylene group; C₁₋₃₀ alkylene; C₁₋₃₀ alkoxylene; C₁₋₃₀ alkenylene; C₆₋₃₀ arylene; C₂₋₃₀ heterocyclic ring; or C₃₋₃₀ cycloalkylene; and

4) z is 0.1 to 0.3 (a mole fraction of the repeating unit represented by Formula (4) among resin molecules).

When the copolymer resin additionally includes the repeating unit represented by Formula (4), it is preferable because the thermal stability of a photo-sensitive composition for forming an insulating film for a touch panel of an organic light emitting display device is improved while the dielectric constant is lowered. In the case of a copolymer resin including the repeating unit represented by Formula (4), it is preferable that the mole fraction of the repeating unit represented by Formula (4) in the copolymer resin is in the range of 0.1 to 0.3. When the mole fraction of the repeating unit represented by Formula (4) is in the range of 0.1 to 0.3, there is an effect of improving the thermal stability of the insulating film for the touch panel and lowering the dielectric constant while maintaining the developability and resolution of the insulating film pattern of the touch panel.

The mole fraction of the repeating unit is a value obtained by dividing the number of moles of each monomer by the total number of moles of each monomer constituting each repeating unit of the copolymer resin.

The total amount of the alkali soluble resin may be included in an amount of 3 wt % to 70 wt %, and more preferably 10 wt % to 40 wt %, based on the total amount of a photo-sensitive composition. When the resin is included within the above range, excellent sensitivity, developability, and adhesion (an adherent property) can be obtained.

The photo-sensitive composition for forming a touch panel insulating film of an organic light emitting display device of the present disclosure may further include, as an alkali soluble resin, an acrylic resin in addition to the copolymer resin. The acrylic resin is a copolymer of a first ethylenically unsaturated monomer and a second ethylenically unsaturated monomer, which is copolymerizable therewith, and it is a resin containing one or more acrylic repeating units. The acrylic resin may be a copolymer of ethylenically unsaturated monomers including 2 to 10 types of acrylates and/or methacrylates, and the weight average molecular weight may be 5,000 g/mol to 30,000 g/mol.

(2) Reactive Unsaturated Compounds

The photo-sensitive composition for an insulating film for a touch panel of an organic light emitting display device according to an embodiment of the present disclosure may include a reactive unsaturated compound with the same structure as the following Formula (5).

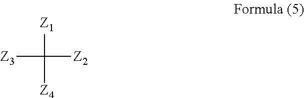

In Formula (5) above, Z₁ to Z₄ have two or more structures of the following Formula (G); and the rest of Z₁ to Z₄ are independently hydrogen, deuterium, a methyl group, an ethyl group, or a methylhydroxy group;

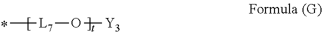

In Formula (G) above,

1) t is an integer from 1 to 20;

2) L₇ is a C₁₋₂₀ alkylene group; and

3) Y₃ is the following Formula (H) or Formula (I); and

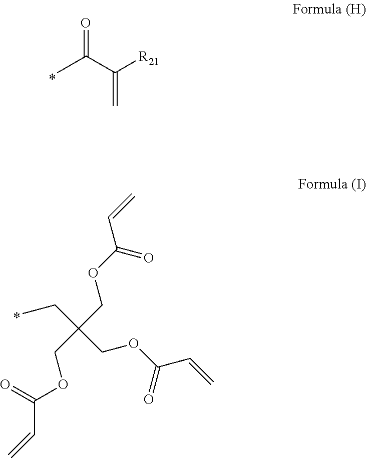

In Formula (H) above, R₂₁ is hydrogen; deuterium; or a methyl group.

The multi-acrylic compound having the same structure as Formula (5) may be used alone or in combination of two or more. Examples thereof include polyfunctional esters of (meth)acrylic acid having at least two ethylenically unsaturated double bonds.

In the present specification, “(meth)acrylic acid” may refer to methacrylic acid, acrylic acid, or a mixture of methacrylic acid and acrylic acid.

Since the reactive unsaturated compound has the ethylenically unsaturated double bond, it is possible to form a pattern having excellent heat resistance, light resistance and chemical resistance by causing sufficient polymerization during exposure to light in the pattern forming process.

Specific examples of the reactive unsaturated compound include ethylene glycol diacrylate, ethylene glycol dimethacrylate, diethylene glycol diacrylate, triethylene glycol diacrylate, triethylene glycol dimethacrylate, 1,6-hexanediol diacrylate, 1,6-hexanediol dimethacrylate, pentaerythritoltriacrylate, dipentaerythritolpentaacrylate, dipentaerythritolhexaacrylate, bisphenol A epoxy acrylate, ethylene glycol monomethyl ether acrylate, trimethylol propane triacrylate, etc.

Examples of the commercially available products of the reactive unsaturated compound are as follows.

Examples of the bifunctional ester of (meth)acrylic acid include AronixM-210, M-240, M-6200, etc. (Toa Kosei Kagaku Kogyo Co., Ltd.), KAYARAD HDDA, HX-220, R-604, etc. (Nippon Kayaku Co., Ltd.), and V-260, V-312, V-335 HP, etc. (Osaka Yuki Kagaku Kogyo Co., Ltd.).

Examples of the trifunctional ester of (meth)acrylic acid include M-309, M-400, M-405, M-450, M-7100, M-8030, and M-8060 (Toa Kosei Kagaku Kogyo Co., Ltd.), KAYARAD TMPTA, DPCA-20, DPCA-60, DPCA-120, etc. (Nippon Kayaku Co., Ltd.), and V-295, V-300, V-360, etc. (Osaka Yuki Kagaku Kogyo Co., Ltd.).

These products may be used alone or in combination of two or more.

The reactive unsaturated compound may be used after treating with an acid anhydride so as to provide improved developability.

The reactive unsaturated compound may be included in an amount of 1 wt % to 40 wt %, for example, 1 wt % to 20 wt %, based on the total amount of the photo-sensitive composition. When the reactive unsaturated compound is included within the above range, sufficient curing occurs during exposure to light in the pattern forming process, thus obtaining excellent reliability, excellent heat resistance, light resistance, and chemical resistance of the pattern, and excellent resolution and adhesion.

(3) Photo-Initiators

The photo-sensitive composition for an insulating film for a touch panel of an organic light emitting display device according to an embodiment of the present disclosure may include a photo-initiator.

The photo-sensitive composition for an insulating film for a touch panel of an organic light emitting display device according to an embodiment of the present disclosure may use, as a photo-initiator, an oxime ester-based compound alone or two or more of them may be used in combination.

The initiator that can be used in combination with the oxime ester-based compound is an initiator used in the photo-sensitive resin composition, and examples of the initiator include an acetophenone-based compound, a benzophenone-based compound, a thioxanthone-based compound, a benzoin-based compound, a triazine-based compound, etc.

Examples of the acetophenone-based compound may include 2,2′-diethoxy acetophenone, 2,2′-dibutoxy acetophenone, 2-hydroxy-2-methylpropiophenone, p-t-butyltrichloroacetophenone, p-t-butyldichloroacetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, etc.

Examples of the benzophenone-based compound may include benzophenone, benzoyl benzoate, methyl benzoyl benzoate, 4-phenyl benzophenone, hydroxybenzophenone, acrylatedbenzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethylketal, etc.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine; 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-trichloromethyl(piperonyl)-6-triazine, 2-4-trichloromethyl (4′-methoxystyryl)-6-triazine, etc.

As the photo-initiator, a carbazole-based compound, a diketone-based compound, a sulfonium borate-based compound, a diazo-based compound, an imidazole-based compound, or a biimidazole-based compound may be used in addition to the above compounds.

As the photo-initiator, which is a radical polymerization initiator, a peroxide-based compound, an azobis-based compound may be used.

Examples of the peroxide-based compound may include ketone peroxides (e.g., methyl ethyl ketone peroxide, methyl isobutyl ketone peroxide, cyclohexanone peroxide, methylcyclohexanone peroxide, acetylacetone peroxide, etc.); diacyl peroxides (e.g., isobutyryl peroxide, 2,4-dichlorobenzoyl peroxide, o-methylbenzoyl peroxide, bis-3,5,5-trimethylhexanoyl peroxide, etc.); hydroperoxides (e.g., 2,4,4,-trimethylpentyl-2-hydroperoxide, diisopropylbenzenehydroperoxide, cumenehydroperoxide, t-butylhydroperoxide, etc.); dialkyl peroxides (e.g., dicumyl peroxide, 2,5-dimethyl-2,5-di(t-butylperoxy)hexane, 1,3-bis(t-butyloxyisopropyl)benzene, etc.); alkyl peresters (e.g., 2,4,4-trimethylpentyl peroxyphenoxyacetate, α-cumylperoxyneodecanoate, t-butyl peroxybenzoate, di-t-butyl peroxytrimethyladipate, etc.); percarbonates (e.g., di-3-methoxybutyl peroxydicarbonate, di-2-ethylhexyl peroxydicarbonate, bis-4-t-butylcyclohexyl peroxydicarbonate, diisopropylperoxydicarbonate, acetylcyclohexylsulfonyl peroxide, t-butyl peroxyaryl carbonate, etc.), etc.

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleric acid), etc.

The initiator may be used together with a photo-sensitizer that causes a chemical reaction by absorbing light to enter an excited state and then transferring the energy. Examples of the photo-sensitizer may include tetraethylene glycol bis-3-mercaptopropionate, pentaerythritol tetrakis-3-mercaptopropionate, dipentaerythritol tetrakis-3-mercaptopropionate, etc.

The initiator may be included in an amount of 0.01 wt % to 10 wt %, for example, 0.1 wt % to 5 wt %, based on the total amount of the photo-sensitive resin composition. When the initiator is included within the above range, it is possible to obtain excellent reliability due to sufficient curing that occurs during exposure to light in the pattern forming process, thereby obtaining excellent heat resistance, light resistance, and chemical resistance of the pattern, and also obtaining excellent resolution and adhesion, and being capable of preventing a decrease in transmittance due to an unreacted initiator.

(4) Hollow Silica Particles

The photo-sensitive composition for an insulating film for a touch panel of an organic light emitting display device according to an embodiment of the present disclosure includes hollow silica particles.

The hollow silica particles may have an average particle diameter of 10 nm to 500 nm, and preferably have an average particle diameter of 50 nm to 400 nm. When the average particle diameter of the hollow silica particles is included in the range of 50 nm to 400 nm, the effect of hollow silica particles exposed on the surface of the pattern is small in forming an insulating film pattern for a touch panel, thus obtaining a high resolution of the pattern and having the effect of lowering the dielectric constant.

The thickness of the outer shell of the hollow silica particles may be 5 nm to 100 nm, but is not limited thereto.

The average particle diameter of hollow silica particles can be determined from photographs obtained by observing the dispersed particles with a transmission electron microscope. The projected area of the particles is determined and the equivalent circle diameter is obtained to thereby define the average particle diameter (conventionally, 300 or more particles are measured to obtain the average particle diameter).

The porosity of the hollow silica particles is preferably 10 vol % to 80 vol %, more preferably 20 vol % to 60 vol %, and most preferably 30 vol % to 60 vol %. It is preferable to set the porosity of the hollow silica particles within the above range so as to lower the dielectric constant and maintain the durability of these particles.

The hollow silica particles may be either crystalline or amorphous, may be monodisperse particles, or may be aggregated particles as long as they satisfy a predetermined particle size. The particles are most preferably spherical, but may be in the shape of beads, a shape with a major axis/short axis ratio of 1 or more, or an irregular shape.

The specific surface area of the hollow silica particles is preferably 10 m²/g to 2,000 m2/g, more preferably 20 m²/g to 1,800 m²/g, and most preferably 50 m²/g to 1,500 m²/g.

The hollow silica particles may be prepared by mixing with a colorant, a dispersant, a resin, or an organic solvent, or may be prepared as a dispersed solution alone without a colorant, and the photo-sensitive resin composition of the present disclosure may include the dispersant.

In order to stabilize dispersion in the dispersed solution or to increase compatibility or binding property with a binder component, the hollow silica particles may be subjected to physical surface treatment (e.g., plasma discharge treatment and corona discharge treatment) or chemical surface treatment with a surfactant, a coupling agent, etc. Among them, use of a coupling agent is preferable. As the coupling agent, an alkoxy metal compound (e.g., a titanium coupling agent or a silane coupling agent) is preferably used. Among them, a silane coupling process is preferable. That is, the surface of the hollow silica particles may be treated with an inorganic or organic material to be dissolved or dispersed in an organic solvent.

As hollow silica particles, commercially available products can be preferably used.

Specific examples of usable hollow silica particles include Sluria series of JGC C&C products (e.g., isopropanol (IPA) dispersion or 4-methyl-2-pentanone (MIBK) dispersion) and OSCAL series; Snowtex series (products of Nissan Chemical Industries, Ltd.) (e.g., IPA dispersion, ethylene glycol dispersion, methyl ethyl ketone (MEK) dispersion, dimethylacetoamide dispersion, MIBK dispersion, propylene glycol monomethyl acetate dispersion, propylene glycol monomethyl ether dispersion, methanol dispersion, ethyl acetate dispersion, butyl acetate dispersion, xylene-n-butanol dispersion, or toluene dispersion); SiliNax (products of Nittetsu Mining Co., Ltd.); PL series (products of Fuso Chemical Co., Ltd.); Aerosil series (products of EVONIK) (e.g., propylene glycol acetate dispersion, ethylene glycol dispersion, or MIBK dispersion); AERODISP series (products of EVONIK), etc.

As for the hollow silica particles, one type of particle may be used alone, or two or more types of particles may be used in combination. When two or more types of particles are used together, for example, hollow silica particles and porous silica particles may be used together.

The hollow silica particles are included in an amount of 20 wt % or less (excluding the solvent) based on the total amount of the photo-sensitive composition.

For example, the hollow silica particles may be included in an amount of 0.1 wt % to 20 wt % based on the total amount of the photo-sensitive composition. When the hollow silica particles are included in an amount of 0.1 wt % to 20 wt % based on the total amount of the photo-sensitive composition, there is an effect of lowering the dielectric constant of the film or pattern being formed.

When the hollow silica particles are included in an amount of less than 0.1 wt % based on the total amount of the photo-sensitive composition, the effect of sufficiently lowering the dielectric constant does not occur. In contrast, when the hollow silica particles are included in an amount of 20 wt % or more based on the total amount of the photo-sensitive composition, developability is deteriorated during the patterning of the photo-sensitive composition, thus resulting in residues or lower resolution, which may be undesirable.

(5) Solvents

The photo-sensitive composition for an insulating film for a touch panel of an organic light emitting display device according to an embodiment of the present disclosure may include a solvent.

As the solvent, materials which have compatibility with the alkali soluble resin, the reactive unsaturated compound, the silica, and the initiator but not reactive thereto may be used.

Examples of the solvent include alcohols (e.g., methanol, ethanol, etc.); ethers (e.g., dichloroethyl ether, n-butyl ether, diisoamyl ether, methylphenyl ether, tetrahydrofuran, etc.); glycol ethers (e.g., ethylene glycol monomethyl ether, ethylene glycol monoethyl ether, etc.); cellosolve acetates (e.g., methyl cellosolve acetate, ethyl cellosolve acetate, diethyl cellosolve acetate, etc.); carbitols (e.g., methylethylcarbitol, diethyl carbitol, diethylene glycol monomethyl ether, diethylene glycol monoethyl ether, diethylene glycol dimethyl ether, diethylene glycol methyl ethyl ether, diethylene glycol diethyl ether, etc.); propylene glycol alkyl ether acetates (e.g., propylene glycol methyl ether acetate, propylene glycol propyl ether acetate, etc.); aromatic hydrocarbons (e.g., toluene, xylene, etc.); ketones (e.g., methyl ethyl ketone, cyclohexanone, 4-hydroxy-4-methyl-2-pentanone, methyl-n-propyl ketone, methyl-n-butyl ketone, methyl-n-amyl ketone, 2-heptanone, etc.); saturated aliphatic monocarboxylic acid alkyl esters (e.g., ethyl acetate, n-butyl acetate, isobutyl acetate, etc.); lactic acid esters (e.g., methyl lactate, ethyl lactate, etc.); oxy acetate alkyl esters (e.g., methyl oxyacetate, ethyl oxyacetate, butyl oxyacetate, etc.); alkoxy acetate alkyl esters (e.g., methoxy methyl acetate, methoxy ethyl acetate, methoxy butyl acetate, ethoxy methyl acetate, ethoxy ethyl acetate, etc.); 3-oxypropionic acid alkyl esters (e.g., methyl 3-oxypropionate, ethyl 3-oxypropionate, etc.); 3-alkoxy propionic acid alkyl esters (e.g., 3-methoxy methyl propionate, 3-methoxy ethyl propionate, 3-ethoxy ethyl propionate, 3-ethoxy methyl propionate, etc.); 2-oxypropionic acid alkyl esters (e.g., methyl 2-oxypropionate, ethyl 2-oxypropionate, propyl 2-oxypropionate, etc.); 2-alkoxy propionic acid alkyl esters (e.g., 2-methoxy methyl propionate, 2-methoxy ethyl propionate, 2-ethoxy ethyl propionate, 2-ethoxy methyl propionate, etc.); 2-oxy-2-methyl propionic acid esters (e.g., 2-oxy-2-methyl methyl propionate, 2-oxy-2-methyl ethyl propionate, etc.); esters (e.g., 2-hydroxyethyl propionate, 2-hydroxy-2-methyl ethyl propionate, hydroxy ethyl acetate, 2-hydroxy-3-methyl methyl butanoate, etc.); ketonic acid esters (e.g., ethyl pyruvate, etc.), etc.

Additionally, the following solvents with a high boiling point may also be used; N-methylformamide, N,N-dimethylformamide, N-methylformanilad, N-methylacetamide, N,N-dimethylacetamide, N-methylpyrrolidone, dimethyl sulfoxide, benzylethylether, dihexyl ether, acetyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, etc.

Among the solvents above, considering compatibility and reactivity, the following solvents may be used: glycol ethers (e.g., ethylene glycol monoethyl ether, etc.); ethylene glycol alkyl ether acetates (e.g., ethyl cellosolve acetate, etc.); esters (e.g., ethyl 2-hydroxypropionate, etc.); carbitols (e.g., diethylene glycol monomethyl ether, etc.); and propylene glycol alkyl ether acetates (e.g., propylene glycol methyl ether acetate, propylene glycol propyl ether acetate, etc.).

The solvent may be included as a balance based on the total amount of the photo-sensitive resin composition, and specifically in the amount of 50 wt % to 90 wt %. When the solvent is included within the above range, the photo-sensitive resin composition has an appropriate viscosity, and thus the processability becomes excellent in preparing the pattern layer.

In another embodiment, the present disclosure may provide an organic light emitting display device.

The organic light emitting display device of the present disclosure includes a substrate 1; an organic light emitting device layer on the substrate; a sealing layer 8 disposed on the organic light emitting device layer; and a touch panel disposed on the sealing layer.

The touch panel includes a first touch electrode 9 formed in contact with the upper part of the sealing layer 8; a second touch electrode 11 disposed on the first touch electrode; and an insulating layer 10 disposed between the first touch electrode and the second touch electrode, in which the insulating film is a cured film of a photo-sensitive composition containing hollow silica particles.

The sealing layer 8 may include at least one inorganic layer 8-2 and at least one organic layer 8-1 that are alternately stacked with each other.

The first touch electrode and the second touch electrode may be formed of ITO or a metal mesh.

The substrate 1 may be a flexible substrate. The substrate may be made of a plastic material having excellent heat resistance and durability, such as polyimide (PI), polyethylene terephthalate (PET), polyethylene naphtalate (PEN), polycarbonate (PC), polyarylate (PAR), polyetherimide (PEI), and polyethersulfone (PES). However, the present disclosure is not limited thereto, and various flexible materials (e.g., metal foil or thin glass) may be used. Meanwhile, the substrate may be a rigid a substrate, and in this case, a substrate may be made of a glass material containing SiO₂ as a main component.

In the case of a bottom emission type in which the image is implemented in the direction of a substrate, the substrate must be formed of a transparent material.

However, in the case of a top emission type in which the image is implemented in the opposite direction of a substrate, the substrate does not necessarily have to be formed of a transparent material. In this case, the substrate can be formed of a metal. When the substrate is formed of metal, the substrate may include at least one selected from the group consisting of carbon, iron, chromium, manganese, nickel, titanium, molybdenum, and stainless steel (SUS), but is not limited thereto.

A TFT layer 2 may be disposed on the substrate 1. The term TFT layer used in this specification refers to a thin film transistor (TFT) array for driving an organic light emitting device, and it refers to a driving part for displaying an image.

The FIGURE shows only an organic light emitting device and a driving thin film transistor for driving the organic light emitting device, which are only for convenience of description and the present disclosure is not limited to what is shown, and it is apparent to those skilled in the art that a plurality of thin film transistors, storage capacitors, and various wirings may be further included.

The TFT layer 2 may be protected by being covered with a planarization layer 3. The planarization layer may include an inorganic insulating layer and/or an organic insulating layer. Examples of the inorganic insulating film that can be used for the planarization layer may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), zirconium oxide (ZrO₂), barium strontium titanate (BST), lead zirconate-titanate (PZT), etc.

In addition, the organic insulating film that can be used for a planarization layer may include common general-purpose polymers (PMMA, PS), polymer derivatives having phenolic groups, acrylic polymers, imide-based polymers, arylether-based polymers, amide-based polymers, fluorine-based polymers, p-xylene-based polymers, vinyl alcohol-based polymers, and blends thereof.

Meanwhile, the planarization layer may have a composite stacked structure of an inorganic insulating film and an organic insulating film.

An organic light emitting device layer may be formed on top of the planarization layer. The organic light emitting device layer may include a pixel electrode 4 formed on the planarization layer, a counter electrode 7 disposed to face it, and an organic material layer 6 interposed therebetween. When a voltage is applied between the pixel electrode and the counter electrode, the organic material layer can emit light. The organic material layer may emit red light, green light, blue light, white light, etc. When the organic material layer emits white light, the organic light emitting display device may further include blue, green, and red color filters so as to represent color images.

The organic light emitting display device may be classified into a bottom emission type, a top emission type, a dual emission type, etc. according to the emission direction.

In an organic light emitting display device of the bottom emission type, the pixel electrode is provided as a light transmitting electrode and the counter electrode is provided as a reflecting electrode.

In an organic light emitting display device of the top emission type, the pixel electrode is provided as a reflective electrode and the counter electrode is provided as a transflective electrode.

In the present disclosure, the top emission type in which the organic light emitting device emits light in the direction of a sealing layer will be described.

The pixel electrode may be a reflective electrode. The pixel electrode may include a stacked structure of a reflective layer and a transparent or semi-transparent electrode layer having a high work function.

The reflective layer may include Ag, Mg, Al, Pt, Pd, Au, Ni, Nd, Ir, Cr, or an alloy thereof.

The transparent or semi-transparent electrode layer may include at least one material selected from among transparent conductive oxide materials, such as indium tin oxide (ITO), indium zinc oxide (IZO), zinc oxide (ZnO), indium oxide (In₂O₃; indium oxide), indium gallium oxide (IGO), aluminum zinc oxide (AZO); aluminum zinc oxide), etc.

The pixel electrode may be formed by patterning in an island shape corresponding to each pixel. Additionally, the pixel electrode may function as an anode electrode.

Meanwhile, a pixel defining layer 5 may be disposed on the pixel electrode so as to cover the edge of the pixel electrode and include a predetermined opening part that exposes the central part of the pixel electrode. An organic material layer 6 including an organic light emitting layer that emits light may be disposed on the area defined by the opening part. The region on which an organic material layer is disposed may be defined as a light emitting region. Meanwhile, when the light emitting region is formed within the opening part of the pixel defining layer, a region protruding by the pixel defining layer is disposed between the light emitting regions. This region may be defined as a non-light emitting area because an organic light emitting layer is not formed in this protruding area.

The counter electrode may be formed as a transmissive electrode. The counter electrode may be a semi-transmissive layer in which a metal having a small work function (e.g., as Li, Ca, LiF/Ca, LiF/Al, Al, Mg, Ag, etc.) is thinly formed. In order to compensate for the high resistance problem of the thin metal semi-transmissive layer, a transparent conductive layer made of a transparent conductive oxide may be stacked on the metal semi-transmissive layer. The counter electrode may be formed over the entire surface of a substrate in the form of a common electrode. In addition, such a counter electrode may function as a cathode electrode.

The polarities of the pixel electrode and the counter electrode as described above may be opposite to each other.

The organic material layer 6 includes an organic light emitting layer that emits light, and the organic light emitting layer may use a low molecular weight organic material or high molecular weight organic material. When the organic light emitting layer is a low-molecular-weight organic layer formed of a low-molecular organic material, a hole transport layer (HTL), a hole injection layer (HIL), etc. may be disposed in the direction of the pixel electrode around the organic light emitting layer, whereas an electron transport layer (ETL), an electron injection layer (EIL), etc. may be disposed in the direction of a counter electrode. Certainly, other functional layers than hole injection layer, hole transport layer, electron transport layer, and electron injection layer may be stacked.

A sealing layer may be disposed on the organic light emitting device layer so as to cover the organic light emitting device layer. The organic light emitting device included in the organic light emitting device layer is composed of an organic material and may easily be deteriorated by external moisture or oxygen. Therefore, in order to protect the organic light emitting device, the organic light emitting device layer must be sealed. The sealing layer is a means for sealing the organic light emitting device layer, and may have a structure in which a plurality of inorganic layers and a plurality of organic layers are alternately stacked.

As for the organic light emitting display device according to this embodiment, it is preferable to form a sealing layer with a thin film in which a plurality of inorganic films and a plurality of organic films are alternately stacked instead of a substrate, flexibility and thinning of the organic light emitting display device can easily be realized by using a thin film as a sealing means.

The sealing layer may include a plurality of inorganic layers and a plurality of organic layers. The inorganic layers and the organic layers may be alternately stacked on each other.

The inorganic layers may be formed of a metal oxide, a metal nitride, a metal carbide, or a combination thereof. For example, the inorganic layers may be made of aluminum oxide, silicon oxide, or silicon nitride. According to another embodiment, the inorganic layers may include a stacked structure of a plurality of inorganic insulating layers. The inorganic layers may perform the functions of preventing the penetration of external moisture and/or oxygen, etc. into the organic light emitting device layer.

The organic layers may be high molecular weight organic compounds. For example, the organic layers may include any one of epoxy, acrylate, and urethane acrylate. The organic layers may perform the functions of relieving internal stress of the inorganic layers or compensating for defects and planarizing the inorganic layers.

The order of stacking the inorganic and organic layers constituting the sealing layer may vary. Although the FIGURE illustrates that an organic layer is stacked on the organic light emitting device layer, this is exemplary, and an inorganic layer may be stacked first on the organic light emitting device layer. In addition, although the uppermost layer of the sealing layer is illustrated as an inorganic film, this is exemplary, and an organic film may be the uppermost layer.

A touch panel may be formed on the sealing layer. The touch panel may include a first touch electrode formed on the sealing layer, a second touch electrode disposed to face the first touch electrode, and an insulating layer interposed therebetween.

The first touch electrode and the second touch electrode may be formed in a grid pattern or specific pattern shape. The first touch electrode may be formed to be in contact with an upper part of the sealing layer, and an inorganic layer may be additionally provided between the sealing layer and the first touch electrode.

The first touch electrode and the second touch electrode may be formed as a transparent conductive film containing indium tin oxide (ITO), indium zinc oxide (IZO), zinc oxide (ZnO), indium oxide (In₂O₃; indium oxide), indium gallium oxide (IGO), aluminum zinc oxide (AZO), etc.; may be formed as a semi-transmissive film formed by thinly forming a metal such as Li, Ca, LiF/Ca, LiF/Al, Al, Mg, Ag, etc. with a small work function; may be formed by a combination of the transparent conductive film and the semi-transmissive film; or may be formed of a metal mesh; and may preferably be formed of a metal mesh among them.

The metal mesh is an electrode prepared by printing an opaque metal (copper, silver, gold, aluminum, etc.) in the form of a grid with a thickness of 1 μm to 7 μm. Due to the use of a metal with high conductivity, the metal mesh has the advantages of a low resistance value, a fast touch response speed, enables easy realization of a large screen, and being cheaper than ITO film. In addition, the metal mesh electrode has excellent durability against repeated bending compared to the ITO electrode, thus being suitable for use as a touch panel electrode for a foldable display.

The insulating layer is formed of a photo-sensitive composition containing the above-mentioned hollow silica particles and a copolymer resin as essential components. In an organic light emitting display device according to another embodiment of the present disclosure, the details about the photo-sensitive composition are the same as those for the photo-sensitive composition for an insulating film for a touch panel of an organic light emitting display device according to an embodiment of the present disclosure described above, and thus will be omitted herein.

When an insulating layer is formed using the photo-sensitive composition for an insulating film for a touch panel of an organic light emitting display device of the present disclosure, an insulating layer having a very low dielectric constant in the range of 2.50 to 3.50 can be formed within the dielectric constant measurement range where the frequency of the AC voltage is 50 KHz to 300 KHz, and thus a touch panel with improved response speed and accuracy can be prepared.

As the touch panel, it is desirable that the touch panel be a capacitive type touch panel which detects the location by recognizing the part where the amount of current is changed using the capacitance in the human body when the user touches it, and calculating the size. The FIGURE illustrates a first touch electrode, an insulating film, and a second touch electrode, which are merely for convenience of description, and the present disclosure is not limited to those illustrated, and it should be apparent to those skilled in the art that Control IC (which converts the analog signal transmitted from the touch panel into a digital signal and controls the coordinate values, etc. needed to determine the coordinates of the touch area) optical clear adhesive, a flexible printed circuit board (FPCB, in which conductive and signal line patterns are formed to thereby transmit various signals to electronic components, etc.), and other various kinds of electronic components and various kinds of wirings may be further included.

Additionally, it is apparent to those skilled in the art that, among the structures of the above-described organic light emitting display device, several functional layers having specific purposes and functions may be additionally disposed between each layer, and the organic light emitting display device of the present disclosure is not limited to the structures and drawings described above.

Hereinafter, Synthesis Examples and Examples according to the present disclosure will be described in detail; however, these Synthesis Examples and Examples of the present disclosure are not limited thereto.

### Synthesis Example 1 (Synthesis of Hollow Silica)

### Synthesis Example 1-1

(Synthesis of Hollow Silica 1)

To a 3,000 mL 3-neck round-bottom flask equipped with a distillation tube, 1,600 g (20 mol) of cyclohexane (Sigma Aldrich), 560 g (0.93 mol) of polyoxyethylenetert-octylphenyl ether (Sigma Aldrich), 360 g (3.57 mol) of 1-hexanol (Sigma Aldrich), and 88 g of water were added, and the mixture was stirred at room temperature for 30 minutes. Then, 5.8 g (0.03 mol) of tetraethylorthosilicate (Sigma Aldrich) was added thereto and the mixture was stirred for additional 2 hours. 45 g of aqueous ammonia (29 wt % of an aqueous solution, Daejung Chemicals) was added thereto, and the mixture was stirred for 10 hours, and 1 g (5.6 mmol) of (3-aminopropyl)trimethoxysilane (Sigma Aldrich), which was diluted in 6 g of ethanol, was added thereto dropwise for 30 minutes. After stirring at room temperature for an additional 6 hours, 1 L of ethanol was added thereto, and 3 g of hollow silica nanoparticles (diameter: 50 nm) was obtained using a centrifuge.

### Synthesis Example 1-2

(Synthesis of Hollow Silica 2)

To a 250 mL 3-neck round-bottom flask equipped with a distillation tube, 1.5 g of poly(vinyl pyrrolidone) (Mw: 40,000, Sigma Aldrich), 10 g (0.096 mol) of styrene (Sigma Aldrich), and 0.5 g (0.003 mol) of azobisisobutyronitrile (Sigma Aldrich) were added, 5 g of purified water (0.278 mol), 45 g of ethanol (0.977 mol), and nitrogen were added thereto while stirring the mixture at 350 RPM. After raising the temperature therein to 70° C. and maintaining the temperature for 3 hours, 0.6 g of [2-(methacryloyloxy)ethyl]trimethylammonium chloride (75 wt % in water, Sigma Aldrich) was added thereto and the mixture was stirred for 3 hours. Then, after cooling to the resultant to 50° C., 4 mL of aqueous ammonia (25 wt %, Sigma Aldrich) was added thereto, and 10 g (0.048 mol) of tetraethylorthosilicate (Sigma Aldrich) was additionally added thereto. The resultant was stirred for an additional 2 hours, cooled, and 100 mL of ethanol was added thereto. The resultant was subjected to centrifugation to thereby obtain 13 g of particles including internal polystyrene within a silica shell having a diameter of 400 nm. The particles were calcined at 800° C. for 1 hour using a furnace (Revodix Inc.) to remove the polystyrene inside the particles, and thereby 2 g of hollow silica nanoparticles (diameter: 400 nm) was obtained.

### Synthesis Example 1-3

(Synthesis of Hollow Silica 3)

2 g of hollow silica nanoparticles (diameter: 1 μm) was obtained in the same manner as in Synthesis Example 1-2, except for reducing the amount of poly(vinyl pyrrolidone) (Mw: 40,000, Sigma Aldrich) from 1.5 g to 0.5 g and reducing the stirring speed from 350 RPM to 250 RPM.

### Synthesis Example 2 (Synthesis of Alkali Soluble Resin)

### Synthesis Example 2-1 to Synthesis Example 2-7

(Synthesis of Binder 1-1 to Binder 1-7)

To a 250 mL 3-neck round-bottom flask equipped with a distillation tube, the compounds listed in Table 1 were added, and the temperature therein was raised to 80° C. and reacted for 4 hours to obtain Binder 1-1 to Binder 1-7 resins, which were dissolved to a concentration of 300% in PGMEA. The weight average molecular weights of the resins measured using GPC are shown in Table 1.

TABLE 1

| | Synthesis | Synthesis | Synthesis | Synthesis | Synthesis | Synthesis | Synthesis |
|---|---|---|---|---|---|---|---|
| | Example | Example | Example | Example | Example | Example | Example |
| | 2-1 | 2-2 | 2-3 | 2-4 | 2-5 | 2-6 | 2-7 |
| | (Binder 1- | (Binder 1- | (Binder 1- | (Binder 1- | (Binder 1- | (Binder | (Binder |
| | 1) | 2) | 3) | 4) | 5) | 1-6) | 1-7) |
| Methacrylic Acid | 3 g | 15 g | 20 g | 15 g | 15 g | 15 g | 15 g |
| (Sigma Aldrich) | (0.04 mol) | (0.18 mol) | (0.24 mol) | (0.18 mol) | (0.18 mol) | (0.18 mol) | (0.18 mol) |
| Styrene | 97 g | 75 g | 65 g | 75 g | 75 g | 75 g | 75 g |
| (Sigma Aldrich) | (0.93 mol) | (0.72 mol) | (0.62 mol) | (0.72 mol) | (0.72 mol) | (0.72 mol) | (0.72 mol) |
| Glycidyl | 8.53 g | 17.06 g | 17.06 g | — | — | 21.32 g | — |
| Methacrylate | (0.06 mol) | (0.12 mol) | (0.12 mol) | | | (0.15 mol) | |
| (Sigma Aldrich) | | | | | | | |
| (7-oxabicyclo | — | — | — | 23.56 g | — | — | 29.44 g |
| [4.1.0]heptan-3- | | | | (0.12 mol) | | | (0.15 mol) |
| yl)methyl | | | | | | | |
| methacrylate | | | | | | | |
| (Sigma Aldrich) | | | | | | | |
| (3-ethyloxetan-3- | — | — | — | — | 22.1 g | — | — |
| yl)methyl | | | | | (0.12 mol) | | |
| methacrylate | | | | | | | |
| (TCI Insulator | | | | | | | |
| Co., Ltd.) | | | | | | | |
| N-Cyclo- | — | — | — | — | — | 21.51 g | 21.51 |
| hexylmaleimide | | | | | | (0.12 mol) | (0.12 mol) |
| (Sigma Aldrich | | | | | | | |
| Co., Ltd.) | | | | | | | |
| AIBN (Radical | 8 g | 8 g | 8 g | 8 g | 8 g | 8 g | 8 g |
| Initiator) | (0.05 mol) | (0.05 mol) | (0.05 mol) | (0.05 mol) | (0.05 mol) | (0.05 mol) | (0.05 mol) |
| (Sigma Aldrich) | | | | | | | |
| PGMEA | 233 g | 233 g | 233 g | 233 g | 233 g | 233 g | 233 g |
| (Solvent) | | | | | | | |
| (Daicel Co., | | | | | | | |
| Ltd.) | | | | | | | |
| Weight Average | 9.970 | 9.660 | 9.520 | 9.710 | 9.750 | 10.090 | 10.170 |
| Molecular | g/mol | g/mol | g/mol | g/mol | g/mol | g/mol | g/mol |
| Weight | | | | | | | |

The mole fraction of each repeating unit in each resin molecule of Binder 1-1 to Binder 1-7 is as follows.

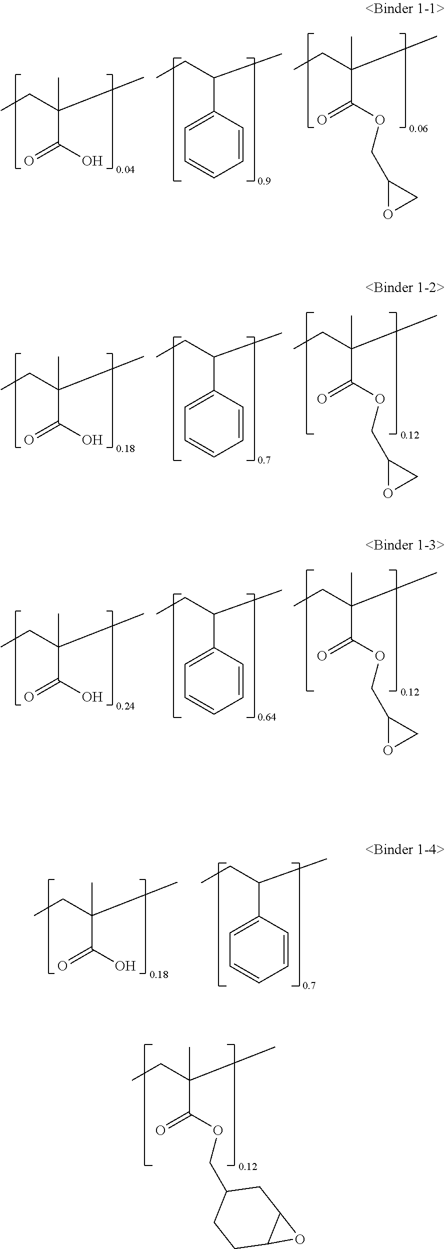

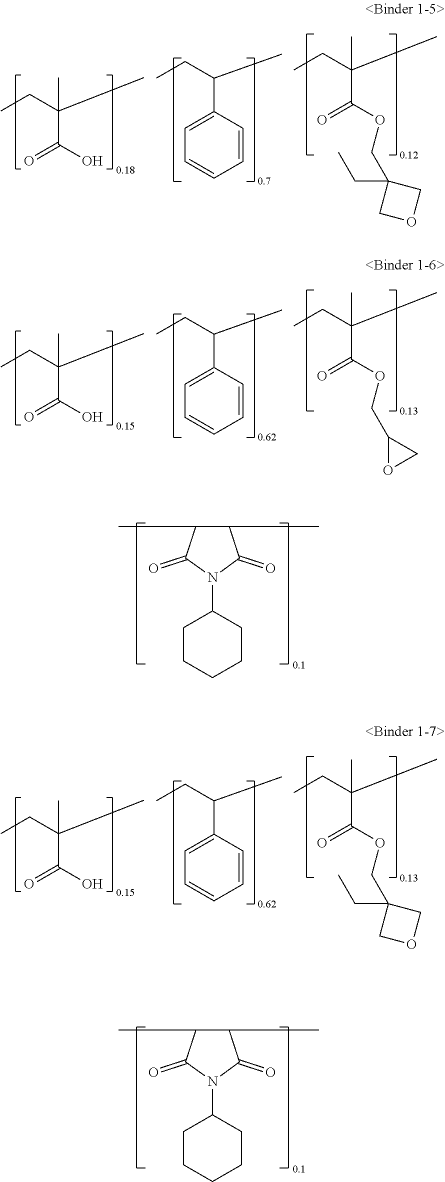

### Synthesis Example 2-8

(Synthesis of Acryl Binder)

To a 250 mL 3-neck round-bottom flask equipped with a distillation tube, 55 g of propylene glycol methacrylate (Sigma Aldrich), 31.5 g (0.18 mol) of benzyl methacrylate (Sigma Aldrich), 2.25 g (0.01 mol) of azobisisobutyronitrile (Sigma Aldrich), 6.75 g (0.07 mol) of methyl methacrylate (Sigma Aldrich), and 6.75 g (0.08 mol) of methacrylic acid (Sigma Aldrich) were added, and the mixture was stirred at 80° C. for 3 hours, and thereby a propylene glycol methylether acetate solution, in which 30 wt % solids of an acrylic binder having a weight average molecular weight of 10,000 were contained, was obtained.

### EXAMPLES

### Example 1 to Example 8

The photo-sensitive compositions were prepared with the compositions (wt %) shown in Table 2 below.

TABLE 2

| Photo-sensitive | | | | | | | | |
|---|---|---|---|---|---|---|---|---|
| Composition | Example 1 | Example 2 | Example 3 | Example 4 | Example 5 | Example 6 | Example 7 | Example 8 |
| Hollow Silica 1 | 3 | 3 | 3 | 3 | 3 | 3 | — | — |
| Hollow Silica 2 | — | — | — | — | — | — | 3 | 3 |
| M600 (Miwon | 7 | 7 | 7 | 7 | 7 | 7 | 7 | 7 |
| Commercial Co., Ltd.) | | | | | | | | |
| OXE-02 (BASF) | 0.5 | 0.5 | 0.5 | 0.5 | 0.5 | 0.5 | 0.5 | 0.5 |
| Binder 1-2 | 8 | — | — | — | — | — | 8 | — |
| Binder 1-3 | — | 8 | — | — | — | — | — | 8 |
| Binder 1-4 | — | — | 8 | — | — | — | — | — |
| Binder 1-5 | — | — | — | 8 | — | — | — | — |
| Binder 1-6 | — | — | — | — | 8 | — | — | — |
| Binder 1-7 | — | — | — | — | — | 8 | — | — |
| Propylene Glycol | 81.5 | 81.5 | 81.5 | 81.5 | 81.5 | 81.5 | 81.5 | 81.5 |
| Methyl Ether Acetate | | | | | | | | |
| (Daicel Co., Ltd.) | | | | | | | | |

### Comparative Example 1 to Comparative Example 6

The photo-sensitive compositions were prepared with the compositions (wt %) shown in Table 3 below.

TABLE 3

| Photo-sensitive | Comparative | Comparative | Comparative | Comparative | Comparative | Comparative |
|---|---|---|---|---|---|---|
| Composition | Example 1 | Example 2 | Example 3 | Example 4 | Example 5 | Example 6 |
| Hollow Silica 1 | 3 | — | — | — | — | 3 |
| Hollow Silica 3 | — | 3 | 3 | 3 | — | — |
| M600 (Miwon | 7 | 7 | 7 | 7 | 7.2 | 7 |
| Commercial Co., Ltd.) | | | | | | |
| OXE-02 (BASF) | 0.5 | 0.5 | 0.5 | 0.5 | 0.5 | 0.5 |
| Binder 1-1 | 8 | — | — | — | — | |
| Binder 1-2 | — | 8 | — | — | 8.3 | |
| Binder 1-3 | — | — | 8 | — | — | |
| Binder 1-4 | — | — | — | 8 | — | |
| Acryl Binder | — | — | — | — | — | 8 |
| Propylene Glycol | 81.5 | 81.5 | 81.5 | 81.5 | 81.5 | 84 |
| Methyl Ether Acetate | | | | | | |
| (Daicel Co., Ltd.) | | | | | | |

The structure of M600 in Tables 2 and 3 is as shown below.

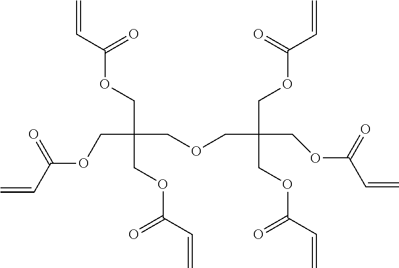 [SMILES: C=CC(=O)OCC(COCC(COC(=O)C=C)(COC(=O)C=C)COC(=O)C=C)(COC(=O)C=C)COC(=O)C=C]

The method of preparing patterns using the above composition is as follows (a photolithography step).

(1) Step of Coating and Film Formation

The red photo-sensitive resin composition described above was applied to a washed 5 cm*5 cm stainless substrate to a thickness of 2 μm using a spin coater, and then heated at a temperature of 100° C. for 1 minute to remove the solvent to thereby form a coating film.

(2) Step of Light Exposure

In order to form a pattern required for the obtained coating film, a mask of a predetermined shape was interposed, and then irradiation was performed with actinic rays of 190 nm to 500 nm. The light exposure machine used was MA-6, and the amount of light exposure was 100 mJ/cm².

(3) Step of Development

Following the step of light exposure, the coating film was developed by dipping it into the AX 300 MIF developer solution (AZEM) at 25° C. for 1 minute, and then it was washed with water to dissolve and remove the unexposed parts, thereby leaving only the exposed parts to form an image pattern.

(4) Step of Post-Processing

In order to obtain an excellent pattern in terms of heat resistance, light resistance, adhesion, crack resistance, chemical resistance, high strength, storage stability, etc. of the image pattern obtained by the above development, post baking was performed in an oven at 230° C. for 30 minutes.

(5) Preparation of Sample for Measurement of Dielectric Constant

In a circle with a diameter of 1 cm, gold was sputtered to a thickness of 100 μm, and the permittivity of the pattern obtained by the post-processing step was measured at 25° C. using an LCR meter (Agilent), according to ASTM D150 (Standard test method for AC loss characteristics and dielectric constant of solid electrical insulation), while varying the frequency of the AC voltage to 50 kHz, 100 kHz, and 300 kHz.

(6) Measurement of Minimum Pattern Size on Substrate

The minimum pattern size of the patterns formed by the photo-sensitive composition of Examples 1 to 8 and Comparative Examples 1 to 6 obtained through the post-processing step was measured using an optical microscope (Nikon) on a substrate.

The dielectric constant of the films obtained through the photolithography step and the maximum resolution (minimum pattern size on the substrate) of the pattern formed on a substrate were measured and are described in Tables 4 and 5.

TABLE 4

| Photo-sensitive | Example | Example | Example | Example | Example | Example | Example | Example |
|---|---|---|---|---|---|---|---|---|
| Composition | 1 | 2 | 3 | 4 | 5 | 6 | 7 | 8 |
| Dielectric | 3.21 | 3.28 | 3.23 | 3.22 | 3.02 | 3.05 | 3.30 | 3.33 |
| Constant At 50 | | | | | | | | |
| kHz | | | | | | | | |
| Dielectric | 3.10 | 3.17 | 3.12 | 3.11 | 2.93 | 2.95 | 3.26 | 3.23 |
| Constant At 100 | | | | | | | | |
| kHz | | | | | | | | |
| Dielectric | 2.98 | 3.11 | 2.97 | 3.00 | 2.75 | 2.78 | 3.17 | 3.18 |
| Constant At 300 | | | | | | | | |
| kHz | | | | | | | | |
| Minimum Pattern | 3.7 | 3.1 | 3.6 | 3.7 | 4.1 | 4.1 | 3.9 | 3.8 |
| Size on Substrate | | | | | | | | |
| μm) | | | | | | | | |

TABLE 5

| | Comparative | Comparative | Comparative | Comparative | Comparative | Comparative |
|---|---|---|---|---|---|---|
| Photo-sensitive | Example | Example | Example | Example | Example | Example |
| Composition | 1 | 2 | 3 | 4 | 5 | 6 |
| Dielectric Constant At | 2.90 | 2.91 | 2.95 | 2.89 | 4.16 | 4.31 |
| 50 kHz | | | | | | |
| Dielectric Constant At | 2.71 | 2.76 | 2.83 | 2.78 | 4.01 | 4.20 |
| 100 kHz | | | | | | |
| Dielectric Constant At | 2.55 | 2.69 | 2.77 | 2.67 | 3.95 | 4.13 |
| 300 kHz | | | | | | |
| Minimum Pattern Size | 11.6 | 5.9 | 6.2 | 6.1 | 3.2 | 8.7 |
| on Substrate μm) | | | | | | |

Comparative Example 1 using Binder 1-1, it can be seen that although the dielectric constant was slightly increased, the resolution was significantly improved as the minimum pattern size on the substrate became smaller. It is speculated that this is due to a difference according to the ratio of a repeating unit of the copolymer resin used as binder resin.

That is, when the mole fraction of the styrene repeating unit is in the range of 0.4 to 0.7 and the mole fraction of the carboxylic acid repeating unit is in the range of 0.1 to 0.3 as in Binder 1-2 to Binder 1-7, the dielectric constant at 50 KHz to 300 KHz of the pattern formed of a photo-sensitive composition containing the same was 3.5 or less, and the minimum pattern size on the substrate was measured to be 4.1 μm or less, and it can be seen that the photo-sensitive composition has very suitable properties for use as an insulating film material for a touch panel of an organic light emitting display device.

In addition, comparing Example 1 and Example 7 in Table 2 with Comparative Example 2 and Comparative Example 5 in Table 3 above, and it can be seen that in the cases of Example 1 and Example 7, hollow silica particles having particle diameters of 50 nm and 400 nm, respectively, were used; in Comparative Example 2, hollow silica having a particle diameter of 1 μm was used; and in Comparative Example 5, hollow silica particles were not included.

When the dielectric constant of the patterns formed by the photo-sensitive compositions of Examples 1 and 7 and Comparative Examples 2 and 5 and the minimum pattern size on the substrate were examined through Table 4 and Table 5 above, the dielectric constant of Comparative Example 2 showed a tendency to be lower compared to those of Examples 1 and 7, but the minimum pattern size on the substrate was significantly increased, and the resolution of the pattern was significantly reduced, thus confirming that these photo-sensitive compositions are not suitable for use as an insulating film material for a touch panel of an organic light emitting display device.

Additionally, it was confirmed that in Comparative Example 5, which did not include hollow silica particles, the dielectric constant was measured to be significantly high compared to those of Examples 1 and 7 and Comparative Example 2, which included hollow silica particles. From these results, it was confirmed that photo-sensitive compositions including hollow silica particles have an effect of lowering the dielectric constant, and that when the use of hollow silica particles with a particle diameter between 10 nm and 500 nm is effective in lowering the dielectric constant while maintaining the resolution of the pattern.

Additionally, when Examples 1 to 6 of Table 2 with Comparative Example 6 of Table 3 were compared, it was confirmed that in the cases of Examples 1 to 6, the copolymer resin of the present disclosure was used as a binder resin, whereas in Comparative Example 6, acryl binder synthesized in Synthesis Example 2-8 was used as a binder resin.

When the dielectric constant of the patterns formed by a photo-sensitive composition of Examples 1 to 6 and Comparative Example 6 and the minimum pattern size on the substrate were compared through Tables 4 and 5 above, it can be seen that the dielectric constant of the patterns formed by the photo-sensitive compositions of Examples 1 to 6 is low while the resolution of the patterns is high. From these results, it can be seen that even in the case of a photo-sensitive composition including hollow silica particles, when hollow silica particles and the copolymer resin from the present disclosure are included in the photo-sensitive composition, the photo-sensitive composition has more excellent effects of lowering the dielectric constant and improving the resolution of the pattern.

Additionally, it was confirmed in Table 4 that in the cases of Example 5 and Example 6 including Binder 1-6 and Binder 1-7 including N-cyclohexylmaleimide monomers, the dielectric constant and resolution were slightly lowered compared to Examples 1 to 4, 7, and 8 where binder resins not including N-cyclohexylmaleimide monomers were used, and it was confirmed that these photo-sensitive compositions are suitable as a material for forming an insulating film for a touch panel of an organic light emitting display device that requires low dielectric constant characteristics.

The photo-sensitive compositions of the present disclosure are not limited to the Examples, but may be prepared in various different forms.

The above description is merely illustrative of the present disclosure, those skilled in the art to which the present disclosure pertains will be able to make various modifications within a range that does not deviate from the essential characteristics of the present disclosure.

Therefore, the Examples disclosed in this specification are for explanation purposes rather than limiting the present disclosure, and the spirit and scope of the present disclosure are not limited by these Examples. The protection scope of the present disclosure should be interpreted by the claims, and all descriptions within the scope equivalent thereto should be construed as being included in the scope of the present disclosure.

### CODE EXPLANATION

| | |
|---|---|
| 1: substrate | 2: TFT layer |
| 3: planarization layer | 4: pixel electrode |
| 5: pixel defining layer | 6: an organic material layer |
| 7: counter electrode | 8: sealing layer |
| 8-1: organic film | 8-2: inorganic film |
| 9: first touch electrode | 10: insulating film |
| 11: second touch electrode | |

What is claimed is:

1. A photo-sensitive composition for an insulating film for a touch panel of an organic light emitting display device, wherein the photo-sensitive composition comprises an alkali soluble resin; a reactive unsaturated compound; a photo-initiator; hollow silica; and a solvent.

2. The photo-sensitive composition of claim 1, wherein the alkali soluble resin comprises a copolymer resin that comprises a repeating unit represented by Formula (1), a repeating unit represented by Formula (2), and a repeating unit represented by Formula (3): 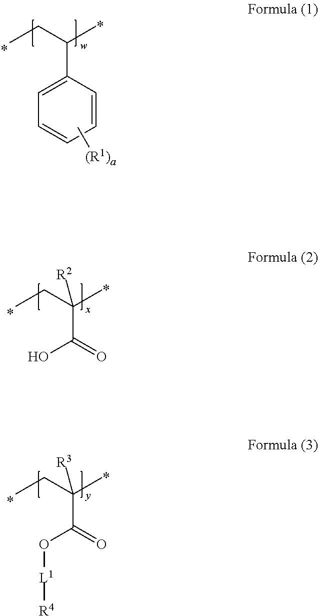
wherein:
1) * represents a binding site;
2) R¹ is selected from the group consisting of hydrogen; deuterium; a halogen; a fluorenyl group; a carbonyl group; an ester group; an ether group; a sulfonic acid group; a C₆₋₃₀ aryl group; a C₂₋₃₀ heterocyclic group comprising at least one heteroatom of O, N, S, Si, and P; a C₆₋₃₀ fused ring group of an aliphatic ring and an aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; and a C₁₋₂₀ alkoxycarbonyl group;
3) a is an integer of 1 to 5;
4) R² to R⁴ are each independently selected from the group consisting of hydrogen; deuterium; a halogen; a fluorenyl group; a C₆₋₃₀ aryl group; a C₂₋₃₀ heterocyclic group comprising at least one heteroatom among O, N, S, Si, and P; a C₆₋₃₀ fused ring group of an aliphatic ring and an aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; a C₁₋₂₀ alkoxycarbonyl group;
5) L¹ is a single bond; a fluorenylene group; C₁₋₃₀ alkylene; C₁₋₃₀ alkoxylene; C₁₋₃₀ alkenylene; C₆₋₃₀ arylene; C₂₋₃₀ heterocyclic ring; or C₃₋₃₀ cycloalkylene;
6) w (a mole fraction of the repeating unit represented by Formula (1) among resin molecules) is 0.4 to 0.7; x (a mole fraction of the repeating unit represented by Formula (2) among resin molecules) is 0.1 to 0.3; and y (a mole fraction of the repeating unit represented by Formula (3) among resin molecules) is 0.1 to 0.3;
7) R¹ to R⁴ are each optionally bound to neighboring groups to form a ring; and
8) R¹ to R⁴, L¹, and the ring formed by the neighboring groups are each optionally further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring with the neighboring substituents.

3. The photo-sensitive composition of claim 2, wherein, R⁴ in Formula (3) is a saturated heterocyclic ring comprising oxygen (O).

4. The photo-sensitive composition of claim 2, wherein i, R⁴ in Formula (3) is one of Formula 3-1 to Formula 3-3:

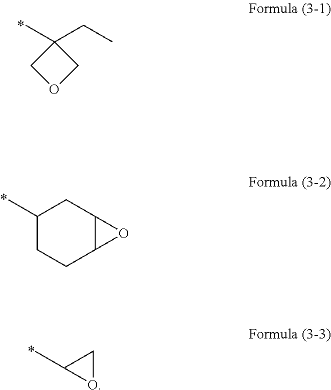

5. The photo-sensitive composition of claim 2, wherein the copolymer resin further comprises a repeating unit represented by Formula (4): 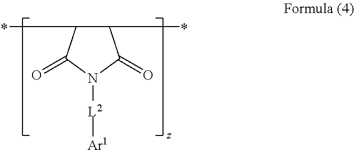
wherein:
1) * represents a bonding part;
2) Ar¹ is selected from the group consisting of hydrogen; deuterium; a halogen; a fluorenyl group; a C₃₋₃₀ cycloalkyl group; a C₆₋₃₀ aryl group; a C₂₋₃₀ heterocyclic group comprising at least one heteroatom among O, N, S, Si, and P; a C₆₋₃₀ fused ring group of an aliphatic ring and an aromatic ring; a C₁₋₂₀ alkyl group; a C₂₋₂₀ alkenyl group; a C₂₋₂₀ alkynyl group; a C₁₋₂₀ alkoxy group; a C₆₋₃₀ aryloxy group; and a C₁₋₂₀ alkoxycarbonyl group;
3) L² is a single bond; a fluorenylene group; C₁₋₃₀ alkylene; C₁₋₃₀ alkoxylene; C₁₋₃₀ alkenylene; C₆₋₃₀ arylene; C₂₋₃₀ heterocyclic ring; or C₃₋₃₀ cycloalkylene; and
4) z (a mole fraction of the repeating unit represented by Formula (4) among resin molecules) is 0.1 to 0.3.

6. The photo-sensitive composition of claim 2, wherein the copolymer resin has an average molecular weight of 1,000 g/mol to 100,000 g/mol.

7. The photo-sensitive composition of claim 1, wherein the alkali soluble resin has a total amount of 3 wt % to 70 wt % based on the total amount of the photo-sensitive composition.

8. The photo-sensitive composition of claim 1, wherein the reactive unsaturated compound comprises a structure represented by Formula (5): 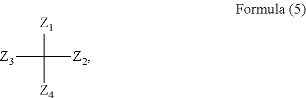
wherein two or more of Z₁ to Z₄ have structures of Formula (G); and the rest of Z₁ to Z₄ are independently hydrogen, deuterium, a methyl group, an ethyl group, or a methylhydroxy group; 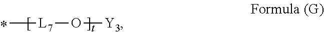
in Formula (G) above, 1) t is an integer of 1 to 20; 2) L₇ is a C₁₋₂₀ alkylene group; and 3) Y₃ is represented by Formula (H) or Formula (I) wherein R₂₁ is hydrogen; deuterium; or a methyl group:

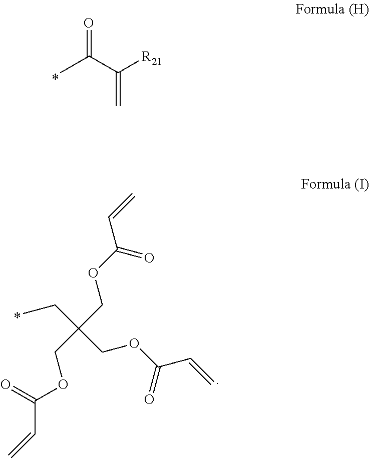

9. The photo-sensitive composition of claim 1, wherein the reactive unsaturated compound is comprised in an amount of 1 wt % to 40 wt % based on the total amount of the photo-sensitive composition.

10. The photo-sensitive composition of claim 1, wherein the photo-initiator comprises one or more compounds selected from the group consisting of oxime ester-based compounds, acetophenone-based compounds, benzophenone-based compounds, thioxanthone-based compounds, benzoin-based compounds, triazine-based compounds, carbazole-based compounds, diketone-based compounds, sulfonium borate-based compounds, diazo-based compounds, imidazole-based compounds, biimidazole-based compounds, peroxide-based compounds, and azobis-based compounds.

11. The photo-sensitive composition of claim 1, wherein the photo-initiator is comprised in an amount of 0.01 wt % to 10 wt % based on the total amount of the photo-sensitive composition.

12. The photo-sensitive composition of claim 1, further comprising a photo-sensitizer.

13. The photo-sensitive composition of claim 1, wherein the hollow silica has a particle size of 10 nm to 500 nm.

14. The photo-sensitive composition of claim 1, wherein the hollow silica has a porosity of 10 vol % to 80 vol %.

15. The photo-sensitive composition of claim 1, wherein the hollow silica has a specific surface area of 10 m²/g to 2,000 m²/g.

16. The photo-sensitive composition of claim 1, wherein the hollow silica is surface-treated physically or chemically.

17. The photo-sensitive composition of claim 1, wherein, the hollow silica is comprised in an amount of 0.1 wt % to 20 wt % based on the solid content excluding a solvent.

18. An insulation film for a touch panel of an organic light emitting display device which is formed from the photo-sensitive composition according to claim 1, wherein the dielectric constant is 2.50 to 3.50 when the frequency of the AC voltage is 50 KHz to 300 KHz.

19. A touch panel, comprising:
a first touch electrode;
a second touch electrode disposed on the first touch electrode; and
the insulating layer of claim 18 disposed between the first touch electrode and the second touch electrode.

20. An organic light emitting display device, comprising:
a substrate;
an organic light emitting device layer on the substrate;
a sealing layer disposed on the organic light emitting device layer; and
the touch panel of claim 19 disposed on the sealing layer.
